(19) United States
(12) Patent Application Publication
(10) Pub. No.: US 2014/0116767 A1
(43) Pub. Date: May 1, 2014

(54) WIRING BOARD WITH BUILT-IN ELECTRONIC COMPONENT AND METHOD FOR MANUFACTURING THE SAME

(71) Applicant: Ibiden Co., Ltd., Ogaki-shi (JP)

(72) Inventors: Kenji SATO, Ogaki-shi (JP); Takaya ENDO, Ogaki-shi (JP)

(73) Assignee: Ibiden Co., Ltd., Ogaki-shi (JP)

(21) Appl. No.: 14/063,036

(22) Filed: Oct. 25, 2013

(30) Foreign Application Priority Data
Oct. 25, 2012 (JP) 2012-235783

(51) Int. Cl. H05K 1/18

(52) U.S. Cl. CPC H05K 1/184
USPC 174/260

(57) ABSTRACT

A wiring board includes a core substrate having cavity penetrating through the substrate, an electronic component accommodated in the cavity and including a body and conductive portions on the body, filling resin filling space in the cavity having the component, a first insulation layer formed on the substrate such that the first layer is covering the substrate and component, a second insulation layer formed on the substrate on the opposite side such that the second layer is covering the substrate and component, a conductive pattern formed on the first layer, and a via hole conductor formed through the first layer such that the via hole conductor is connecting one of the conductive portions and conductive pattern. The component is positioned in the cavity such that the component is inclined with respect to surfaces of the substrate and has main surface forming inclination angle with main surface of the substrate.

### CROSS-REFERENCE TO RELATED APPLICATIONS

The present application is based upon and claims the benefit of priority to Japanese Patent Application No. 2012-235783, filed Oct. 25, 2012, the entire contents of which are incorporated herein by reference.

### BACKGROUND OF THE INVENTION

1. Field of the Invention

The present invention relates to a wiring board having a built-in electronic component, and a method for manufacturing the same.

2. Description of Background Art

Japanese Laid Open Patent Publication No. 2001-345560 describes an example of a product in which the electronic component is positioned in the cavity of a wiring board. The entire contents of this publication are incorporated herein by reference.

### SUMMARY OF THE INVENTION

According to one aspect of the present invention, a wiring board with a built-in electronic component includes a core substrate having a cavity portion penetrating through the core substrate, an electronic component accommodated in the cavity portion of the core substrate and including a body portion and multiple conductive portions formed on a surface of the body portion, a filling resin filling a space formed in the cavity portion having the electronic component positioned in the cavity portion, a first resin insulation layer formed on the core substrate such that the first resin insulation layer is covering the core substrate and the electronic component, a second resin insulation layer formed on the core substrate on the opposite side with respect to the first resin insulation layer such that the second resin insulation layer is covering the core substrate and the electronic component, a conductive pattern formed on the first resin insulation layer, and a via hole conductor formed through the first resin insulation layer such that the via hole conductor is connecting one of the conductive portions of the electronic component and the conductive pattern formed on the first resin insulation layer. The electronic component is positioned in the cavity portion of the core substrate such that the electronic component is inclined with respect to surfaces of the core substrate and has a main surface forming an inclination angle with respect to a main surface of the core substrate.

According to another aspect of the present invention, a method of manufacturing a wiring board with a built-in electronic component includes preparing a core substrate having a cavity portion penetrating through the core substrate, positioning an electronic component in the cavity portion of the core substrate, forming a first resin insulation layer on the core substrate such that the first resin insulation layer covers the core substrate and the electronic component positioned inside the cavity portion of the core substrate, making a portion of a resin material forming the first resin insulation layer to flow into a gap formed between a wall forming the cavity portion and the electronic component such that the portion of the resin material fills the gap between the wall forming the cavity portion and the electronic component, forming a second resin insulation layer on the core substrate on the opposite side with respect to the first resin insulation layer such that the second insulation layer covers the core substrate and the electronic component positioned inside the cavity portion of the core substrate, making a portion of a resin material forming the second resin insulation layer to flow into the gap between the wall forming the cavity portion and the electronic component such that the electronic component is inclined with respect to surfaces of the core substrate and has a main surface forming an inclination angle with respect to a main surface of the core substrate, forming a conductive pattern on one of the first resin insulation layer and the second resin insulation layer, and forming a via hole conductor through the one of the first resin insulation layer and the second resin insulation layer such that the via hole conductor connects one of conductive portions of the electronic component and the conductive pattern formed on the one of the first resin insulation layer and the second resin insulation layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a perspective plan view illustrating a wiring board with a built-in electronic component according to an embodiment;

FIG. 2 is a cross-sectional view of the wiring board with a built-in electronic component according to the embodiment;

FIG. 3 is a cross-sectional view of a core wiring board used as a start material in the embodiment;

FIG. 4 is a cross-sectional view of the core wiring board in which a cavity is formed;

FIG. 5 is a cross-sectional view of the core wiring board to which an adhesive tape is laminated;

FIG. 6 is a cross-sectional view of the core wiring board to which an MLCC is mounted;

FIG. 7 is a cross-sectional view of the core wiring board which has undergone a first lamination;

FIG. 8 is a cross-sectional view of the core wiring board which has undergone a second lamination;

FIG. 9 is a view schematically illustrating an inclination angle of the MLCC in FIG. 8;

FIG. 10 is a cross-sectional view of the core wiring board in which an outer-layer pattern is formed; and

FIG. 11 is a cross-sectional view of the wiring board with a built-in electronic component in which a protective insulation layer or the like is formed.

### DETAILED DESCRIPTION OF THE EMBODIMENTS

The embodiments will now be described with reference to the accompanying drawings, wherein like reference numerals designate corresponding or identical elements throughout the various drawings.

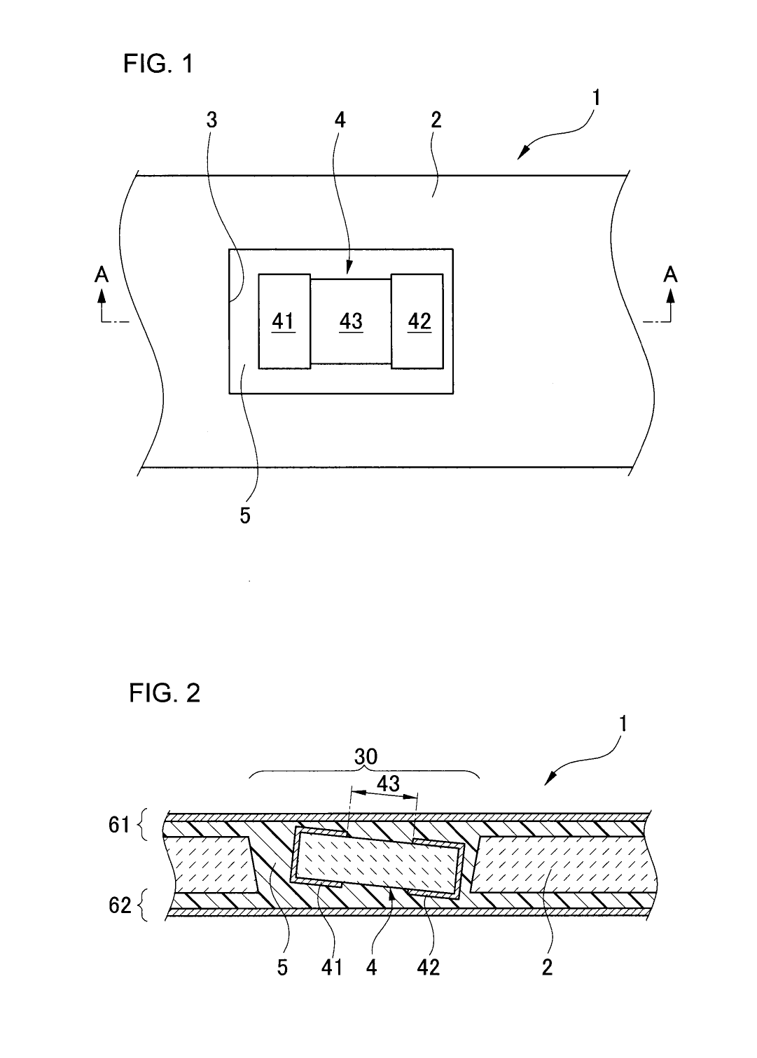

A wiring board with a built-in electronic component according to an embodiment of the present embodiment is structured as illustrated in a plan view of FIG. 1 and a sectional view of FIG. 2. As illustrated in FIG. 1, the wiring board 1 with a built-in electronic component according to the present embodiment is a wiring board prepared by forming a cavity 3 in a core wiring board 2 and mounting an electronic component 4 in the cavity 3. The core wiring board 2 is a well-known wiring board formed by laminating conductive layers and insulation layers. The cavity 3 is a through hole formed by boring through a portion of the core wiring board 2. The electronic component 4 is accommodated in the cavity 3 in the wiring board 1 with a built-in electronic component of FIG. 1. Within the cavity 3, portions other than the portion occupied by the electronic component 4 are filled with filling resin 5.

The electronic component 4 in the present embodiment is a Multi-Layer Ceramic Capacitor (MLCC). Hereinafter, it is called MLCC 4. The overall shape of the MLCC 4 is a rectangular flat plate. The MLCC 4 has regions with a surface covered by electrodes (41, 42) at respective ends in a longitudinal direction. The electrodes (41, 42) are conductive portions connected to inner conductors of the MLCC 4. The electrodes (41, 42) are arranged along opposite sides of the MLCC 4. A region 43 which is not covered by electrodes is located between the electrodes (41, 42).

The cross-sectional view of FIG. 2 illustrates a position along line (A-A) in FIG. 1. As shown in FIG. 2, an upper surface and a lower surface of the wiring board 1 with a built-in electronic component according to the present embodiment are covered by upper layers (61, 62). The upper layers (61, 62) cover main surfaces (upper surfaces and lower surfaces of the core wiring board 2 and MLCC 4 in FIG. 2) of the core wiring board 2 and the MLCC 4. Upper layers 61 and 62 are described in detail below. The MLCC 4 is positioned with a slightly inclined posture in the cavity 3 of the core wiring board 2. The MLCC 4 is not positioned in the center of the cavity 3 but is shifted toward the right side from the center in a left-right direction (the longitudinal direction of the MLCC 4) in FIGS. 1 and 2. That is, the distance between a wall surface 31 of the cavity 3 and the MLCC 4 is longer at a position near the electrode 41 of the MLCC 4 and shorter at a position near the electrode 42 of the MLCC 4.

A manufacturing process of the wiring board 1 with a built-in electronic component of the present embodiment is described below.

### Preparation of Core Wiring Board

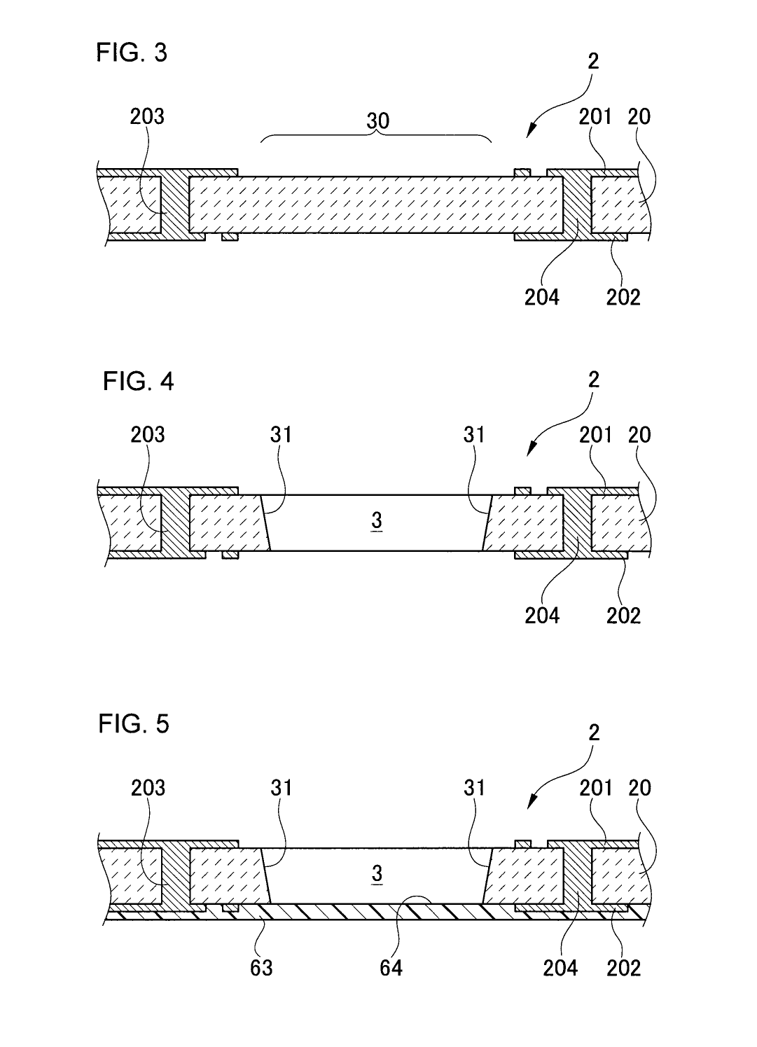

A core wiring board 2 used as a starting material in the present embodiment is illustrated in FIG. 4 and obtained by forming a cavity 3 in a laminated wiring board 20 shown in FIG. 3. The laminated wiring board 20 of FIG. 3 is a well-known wiring board formed by laminating conductive layers and insulation layers. Wiring patterns (201, 202) are formed on the upper and lower surfaces of the laminated wiring board 20 respectively. An upper layer is laminated on the wiring patterns (201, 202) so that the wiring patterns (201, 202) will become inner layer patterns.

Aside from the wiring patterns (201, 202), inner wiring patterns may also be formed in the laminated wiring board 20. However, neither the wiring patterns (201, 202) nor the inner wiring patterns exist within a region 30 in which the cavity 3 is formed. In the laminated wiring board 20 of FIG. 3, filled through holes (203, 204) are formed in positions within a region other than the region 30. Electrical conduction between the wiring patterns (201, 202) is made through filled through holes (203, 204) enable.

The cavity 3 is formed by boring through the region 30 of the laminated wiring board 20 of FIG. 3. This results in the state of FIG. 4. The cavity 3 is a through hole that penetrates through the laminated wiring board 20 in a thickness direction. The cavity 3 is formed by irradiating a laser, for example, at a position corresponding to the contour of the cavity 3. When the cavity 3 is formed by laser processing, a wall surface 31 of the cavity 3 becomes an inclined surface which is open toward a light source (see FIG. 4). That is, in the cavity 3 of FIG. 4, a size of an opening in the lower-surface side is slightly smaller than a size of an opening in the upper-surface side.

### Inner-Layer Surface Treatment

Next, an inner-layer surface treatment is performed with respect to the laminated wiring board 20 with the cavity 3 formed therein. That is, a surface roughening treatment is performed on the wiring patterns (201, 202) on the surfaces of the laminated wiring board 20. This treatment is to improve adhesion between the interlayer insulation layers to be formed in the following step and the wiring patterns (201, 202). Specifically, the laminated wiring board 20 is immersed in a sulfuric acid-hydrogen peroxide type soft etching agent. As the surface roughening agent, a commercially available surface roughening agent for copper and the like is used. In this case, treatment conditions are set to conditions generally used for such soft etching.

### Tape Lamination

Subsequently, an adhesive tape 63 is laminated to the laminated wiring board 20 which has undergone the surface roughening treatment, resulting in the state of FIG. 5. This step is to temporarily fix the MLCC 4 when the MLCC 4 is accommodated in the cavity 3. Therefore, as the adhesive tape 63, a single-sided adhesive tape where an adhesive surface 64 is set on one side is used. The adhesive tape 63 is laminated in such a manner that the adhesive surface 64 faces the laminated wiring board 20. Thereby, one end of the cavity 3 of the laminated wiring board 20 will be covered by the adhesive tape 63. That is, the adhesive tape 63 serves as the bottom of the cavity 3, and the adhesive surface 64 is exposed in the bottom of the cavity 3.

In a case where the cavity 3 is formed by irradiating a laser, it is preferred for the adhesive tape 63 to be laminated to the surface of the laminated wiring board which is on the opposite side of the light source during the laser irradiation. That is, when the wall surface 31 of the cavity 3 is an inclined surface, it is preferred for the inclined surface to be exposed through to the opening which is in the opposite side of the adhesive tape 63. The adhesive tape 63 laminated here will be removed later, and does not remain in the final product.

### Mounting of MLCC

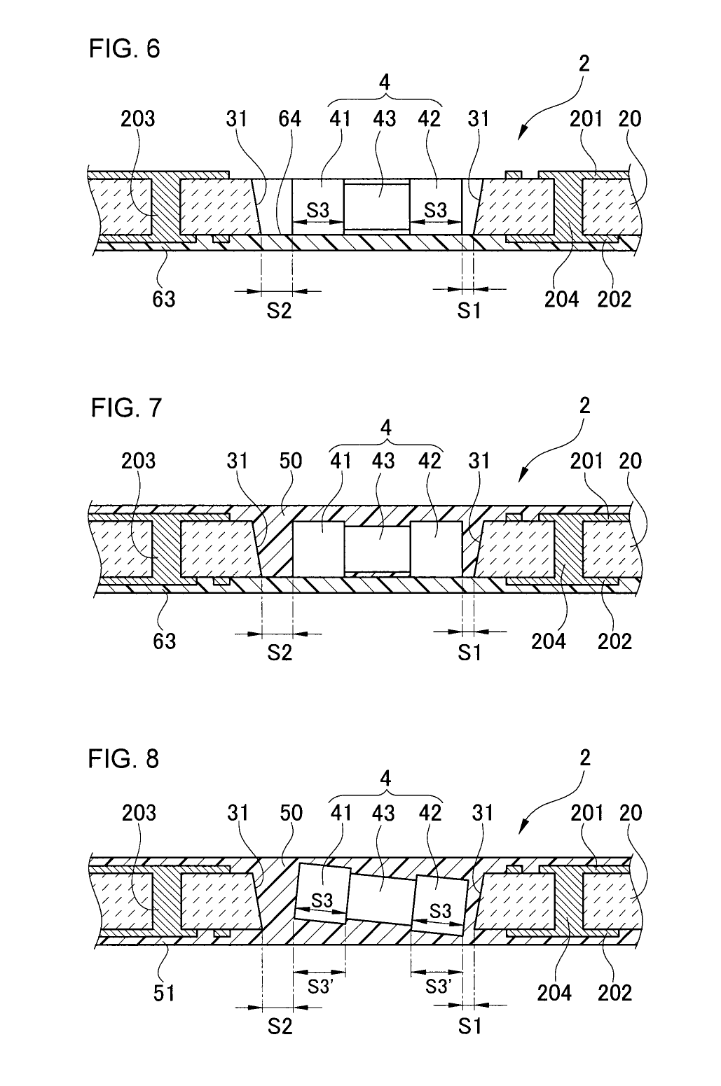

Subsequently, the MLCC 4 is mounted to the laminated wiring board 20 after the lamination, resulting in the state of FIG. 6. That is, the MLCC 4 is accommodated in the cavity 3 of the laminated wiring board 20. Thereby, the MLCC 4 is pasted to the adhesive surface 64 of the adhesive tape 63, so that the MLCC 4 is not likely to be accidently removed. This state is called a temporary fixed state.

At this time, the MLCC 4 is positioned not in the center of the cavity 3 but in a portion shifted toward any side of the laminated wiring board 20 in a board surface direction. In the example of FIG. 6, the MLCC 4 is shifted to be near the right side in the cavity 3. That is, a distance between the wall surface 31 of the cavity 3 and the MLCC 4 is not uniform on the left and right sides of the MLCC 4. A distance (S1) on the right side is greater than a distance (S2) on the left side. The arrangement of the MLCC 4 in the cavity 3 is intentionally made off-center in order to make the MLCC 4 incline to the laminated wiring board 20 in a later process. Therefore, the greater distance (S2) is more than 120% of the smaller distance (S1). This is because the MLCC 4 will be seldom inclined in the later process when a difference between the distance (S2) and the distance (S1) is too small.

In the MLCC 4 of FIG. 6, the electrodes 42 are arranged along a right side edge portion and the electrodes 41 are arranged along a left side edge portion. Here, a width (S3) of the electrode 41 or electrode 42 is greater than the greater distance (S2). The reason is described later. More preferably, the width (S3) may be greater than the sum of the distance (S2) and the distance (S1). When the width (S3) differs between the electrode 41 and the electrode 42, even the electrode with the smaller width (S3) is made to satisfy the above condition. The width (S3) of the electrode (41 or 42) is a size in a direction in which the distances (S1) and (S2) are connected.

### First Lamination

Next, an upper interlayer insulation layer is laminated. Here, a lamination to a surface on the opposite side of the adhesive tape 63 is performed as a first lamination. Thus, as illustrated in FIG. 7, an upper interlayer insulation layer 50 is laminated on a surface of the laminated wiring board 20 opposite the adhesive tape 63. For this reason, a resin film is laminated on the same surface of the laminated wiring board 20. In this state, the upper interlayer insulation layer 50 covers each of the main surfaces of the laminated wiring board 20 and the MLCC 4. For the resin film, an epoxy resin or other thermosetting resins may be used. Especially, an uncured resin is used. In particular, a resin of a semi-cured state called B-stage is preferably used. Moreover, a resin film without containing a glass cloth (core member) is preferred. This lamination is preferred to be conducted under reduced pressure.

Subsequently, the laminated wiring board 20 and the resin film laminated on the laminated wiring board 20 are pressed in a thickness direction. Accordingly, a portion of resin that forms the resin film is pressed into a gap between the wall surface 31 and the MLCC 4 positioned in the cavity 3. In this way, the gap is filled with the filling resin 5. That is, the filling resin 5 is originally part of the resin that makes up the resin film. The portion of the resin film remaining on the surface of the laminated wiring board 20 or the MLCC 4 without being pressed into the gap serves as the upper interlayer insulation layer 50. Therefore, the filling resin 5 is contiguous to the upper interlayer insulation layer 50 without any interface being formed.

Pressure and temperature for the pressing are set to such a degree that the resin of the upper interlayer insulation layer 50 and the filling resin 5 will not be cured. FIG. 7 illustrates the state after this pressing. A thickness of the upper interlayer insulation layer 50 after the pressing is approximately 10 to 20 μm.

Here, when the wall surface 31 is an inclined surface as described above, the resin film is laminated on the surface of the laminated wiring board 20 where the inclined surface is exposed. For this reason, the filling resin 5 to fill the gap between the wall surface 31 and the MLCC 4 is introduced into the gap from a direction in which the inclined surface is exposed. Therefore, the filling resin easily enters the gap.

### Second Lamination

Next, a second lamination of an upper interlayer insulation layer is performed. That is, an upper interlayer insulation layer is laminated to a surface of the laminated wiring board opposite the surface on which the upper interlayer insulation layer 50 has been laminated with the first lamination. Thus, the adhesive tape 63 is removed first. Since the adhesion of the adhesive tape 63 itself is not so strong, the adhesive tape 63 can be easily removed from the laminated wiring board 20. At this time, the MLCC 4 remains in the cavity 3 of the laminated wiring board 20 without being removed from the laminated wiring board 20 when the adhesive tape 63 is removed. That is, the MLCC 4 is separated from the adhesive tape 63. While only one surface of the MLCC 4 is held by the adhesive tape 63, all of the other surfaces of the MLCC 4 are held by the upper interlayer insulation layer 50 and the filling resin 5.

Subsequently, a resin film is laminated on the surface of the laminated wiring board 20 from which the adhesive tape 63 has been removed. As illustrated in FIG. 8, this results in the upper interlayer insulation layers (50, 51) being laminated respectively on the surfaces of the laminated wiring board 20. For this reason, the resin film is laminated on the stripped surface of the laminated wiring board 20. In this state, the same as with the upper interlayer insulation layer 50, the upper interlayer insulation layer 51 covers each of the main surfaces of the laminated wiring board 20 and the MLCC 4. As the resin film, the same kind of resin film used for the first lamination may be used. This lamination is also preferred to be performed under reduced pressure.

The resin film formed through the second lamination is also pressed in a thickness direction. Conditions such as temperature and pressure for the pressing performed after the second lamination may be the same as those for the pressing performed after the first lamination. That is, at this time, the upper interlayer insulation layers (50, 51) and the filling resin 5 have not been cured yet. During this second pressing, a portion of the resin is pressed into the gap between the wall surface 31 and the MLCC 4 from the newly laminated resin film, i.e., the upper interlayer insulation layer 51.

On the other hand, this region is already filled with the filling resin 5 formed to be contiguous to the upper interlayer insulation layer 50 during the first pressing. Therefore, the filling resin 5 from the upper interlayer insulation layer 50 will be slightly pressed back by the resin that is pressed in from the upper interlayer insulation layer 51. As a result, there is no change before and after the second pressing to a state in which resin fills a region other than the region occupied by the MLCC 4 in the cavity 3. Therefore, in the following description, the resin that is pressed in from the upper interlayer insulation layer 50 and the resin that is pressed in from the upper interlayer insulation layer 51 are not distinguished from each other and are collectively called filling resin 5. However, strictly speaking, there is an interface between them.

During the second pressing, the MLCC 4 in the cavity 3 rotates slightly. This results in a state where the main surface of the MLCC 4 inclines with respect to the main surface of the laminated wiring board 20. This is the reason for the inclination described above. The reason that the MLCC 4 rotates slightly during the second pressing is that the force of pressing the resin from the upper interlayer insulation layer 51 differs between one side of the MLCC 4 and the opposite side of the MLCC 4.

That is, as described above, the distances between the MLCC 4 and the wall surface 31 are not uniform on the left and right side of the MLCC 4, as is illustrated in the drawings. For this reason, the pressing-in of the resin from the upper interlayer insulation layer 51 is strong in the gap with a greater distance (S2), which is illustrated on the left side in the drawings, but the pressing-in of the resin is not so strong in the gap with a shorter distance (S1), which is illustrated on the right side in the drawing. Thereby, the MLCC 4 rotates slightly so that an end on the left side in the drawing moves more away from the upper interlayer insulation layer 51, and thus the MLCC 4 is inclined. FIG. 8 illustrates a state where the MLCC 4 is inclined in this way. In the state of FIG. 8, i.e., after the pressing, a thickness of the upper interlayer insulation layer 51 is substantially the same as that of the upper interlayer insulation layer 50 described above.

Especially when the wall surface 31 is inclined as described above and when the first lamination of the resin film is performed on the surface of the laminated wiring board in which the inclined surface is exposed, the second lamination of the resin film is performed on the surface of the laminated wiring board in which the inclined surface is not exposed. For this reason, the pressing-back of the resin during the second pressing occurs in the surface in which the inclined surface is not exposed. Therefore, in the gap with the smaller distance (S1), the pressing-back of the resin is unlikely to occur due to interference of the inclination of the wall surface 31. On the other hand, in the gap with the larger distance (S2), the pressing-back of the resin occurs regardless the degree of the inclination of the wall surface 31. Accordingly, the difference in the amount of pressing-back between the gap with the distance (S1) and the gap with the distance (S2) is significant. Therefore, the MLCC 4 rotates more certainly.

However, even though the MLCC 4 rotates, the MLCC 4 does not rotate to such a degree to cause protrusion of any edge of the MLCC 4 from the surface of the upper interlayer insulation layers (50, 51). The pressing-in does not fall below 5 μm even in a position at which the upper interlayer insulation layers (50, 51) are thinnest. That is, even though the MLCC 4 is inclined, the inclination is not so steep. As represented by (S3′) in FIG. 8, the substantial width of the electrodes (41, 42) in the state where MLCC 4 inclines is slightly smaller than the width (S3) described in FIG. 6. Thus, it is more preferable for the substantial width (S3′) to satisfy the relationship between the distances (S1) and (S2) described above. The substantial width (S3′) means a width when the electrodes (41, 42) are viewed in a direction perpendicular to a board surface of the laminated wiring board 20 in the state in which the MLCC 4 inclines.

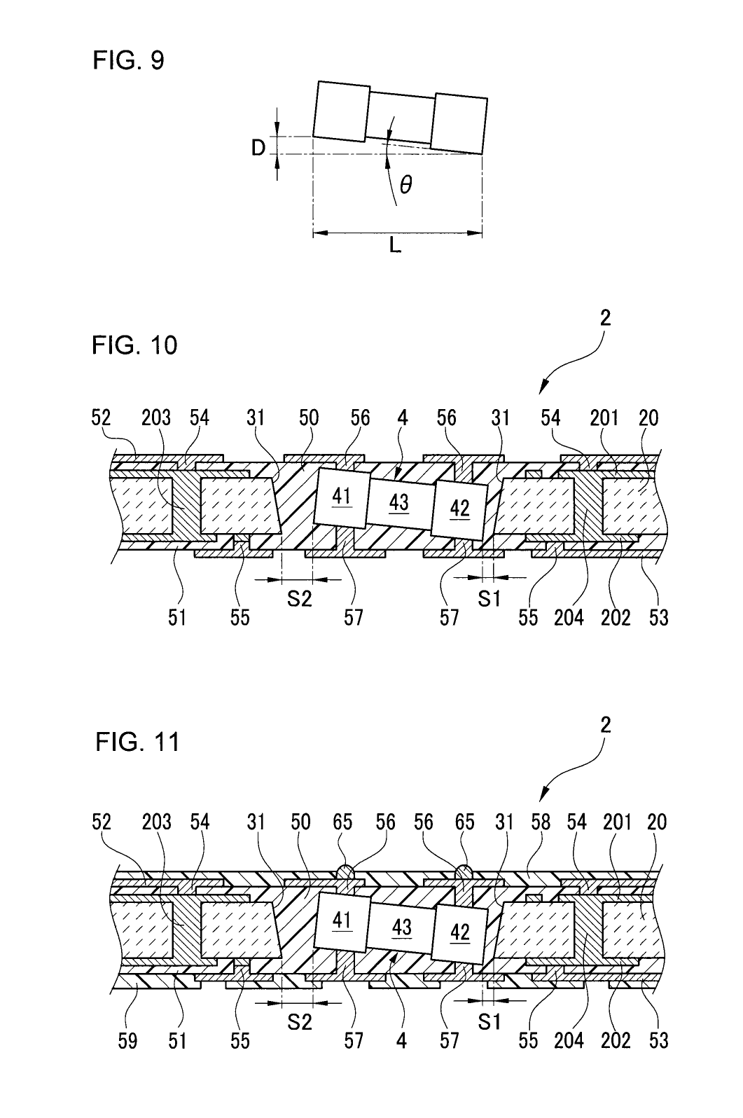

When a difference in height between left and right ends of the MLCC 4 in FIG. 8 is set at “D” and a size of the MLCC 4 in a left-right direction (longitudinal direction) is set at “L” (refer to FIG. 9), “D” is approximately 12 μm. Since “L” is approximately 1 mm, i.e., 1000 μm, the tangent (D/L) of an inclination angle θ is about 0.012 in general. A preferred range of tan θ is 0.005 to 0.02. That is because the MLCC 4 is not viewed that it inclines substantially when tan θ is too small, while the upper interlayer insulation layers (50, 51) may become partially too thin when tan θ is too great. In the MLCC 4 in FIGS. 2 and 8, the inclination angle is illustrated with a slight exaggeration to better help understanding. The inclination angle of the MLCC 4 may be within the above-described range in the cross-sectional view of FIG. 8. That is, in FIG. 6, a cross-sectional view may be taken in a direction (direction (A-A) in FIG. 1) in which the distances (S1) and (S2) which differ in size are connected. When the MLCC 4 inclines in a transverse direction, a range of tan θ is preferred to be 0.01 to 0.04.

### Curing

Subsequently, a curing treatment is performed. That is, after the second lamination, the laminated wiring board 20 is heated so that the thermosetting resin is cured. Thereby, the MLCC 4 is fixed in the posture illustrated in FIG. 8.

### Formation of Outer Layer and the Like

Next, an outer-layer pattern and the like are formed, resulting in the state of FIG. 10. In the laminated wiring board 20 shown in FIG. 10, outer-layer wiring patterns (52, 53) are formed on the upper interlayer insulation layers (50, 51). Via holes (54, 55) to conduct electricity respectively to the inner layer wiring patterns (201, 202), and via holes (56, 57) to conduct electricity respectively to the electrodes (41, 42) of the MLCC 4, are formed respectively in the outer-layer wiring patterns (52, 53). The diameter of the via holes (54 to 57) is approximately 50 to 80 μm.

Holes for forming the via holes (54 to 57) in the upper interlayer insulation layers (50, 51) are opened by irradiating a laser. Alternatively, they can also be opened using photolithography and dissolution. Holes for forming the via holes (54 to 57) are opened more easily especially by using the upper interlayer insulation layers (50, 51) that do not have glass cloth. However, even when the upper interlayer insulation layers (50, 51) do have glass cloth, a via opening is not impossible. Formation of a copper layer for the outer-layer wiring patterns (52, 53) is performed using electroless plating. Alternatively, the copper layer may be formed by using a copper-clad resin film for the resin film used at the time of “5. first lamination” and “6. second lamination.”

Then, protective insulation layers (58, 59) and bumps 65 are formed at a final step, resulting in the state of FIG. 11. Next, by checking a capacitance value of the MLCC 4 and insulation between each portion using an electric test instrument, manufacturing of the wiring board 1 with a built-in electronic component of the present embodiment is completed. The upper interlayer insulation layers (50, 51), the outer-layer wiring patterns (52, 53), and the protective insulation layers (58, 59) are collectively called “upper layers (61, 62)” in the description of FIG. 2.

In the wiring board 1 with a built-in electronic component of the present embodiment manufactured as described above, the inclination of the MLCC 4 has the following advantages. That is, electrical conduction reliability between the MLCC 4 and the outer-layer wiring patterns (52, 53) at the via holes (56, 57) is high. A contact area between the electrodes (41, 42) of the MLCC 4 and the via holes (56, 57) is increased in proportion to the inclination angle of the MLCC 4. Although the diameter of the via holes (56, 57) itself is not as great as described above, the contact area is increased by the inclination of the MLCC 4.

In the wiring board 1 with a built-in electronic component of the present embodiment, the via holes (56, 57) do not deviate from a region in which the electrodes (41, 42) are formed. As described above, the width (S3) of the electrode 41 or electrode 42 is greater than the larger distance (S2). Therefore, even though positioning accuracy in the arrangement of the MLCC 4 is low in the step “4. mounting of MLCC 4”, the electrodes (41, 42) are certainly located in the positions at which the via holes (56, 57) are formed. In wiring board 1 with a built-in electronic component of the present embodiment, the reliability of the via holes (56, 57) is high due to the effect of these advantages.

On the other hand, although the MLCC 4 inclines, no edge portion of the MLCC 4 is in direct contact with the outer-layer wiring patterns (52, 53). That is because the inclination angle of the MLCC 4 is not so steep. Therefore, the electrodes (41, 42) of the MLCC 4 and the outer-layer wiring patterns (52, 53) are not in contact with each other in positions other than the via holes (56, 57). That is, short-circuiting does not occur at a portion which is not supposed to be electrically conducted.

In the wiring board 1 with a built-in electronic component according to the present embodiment described above, the MLCC 4 is positioned off center in the cavity 3 when the MLCC 4 is accommodated in the cavity during the manufacturing process. This causes a difference in the distance (S1) and the distance (S2), which are between the wall surface 31 of the cavity 3 and the MLCC 4. For the distance (S1) and the distance (S2), this also causes a difference in the degree of the pressing-back of the resin from a new resin film when the pressing is performed after the second lamination. In this way, when formation of the upper interlayer insulation layers (50, 51) is finished, the MLCC 4 inclines. Thereby, the contact area between the MLCC 4 and the via holes (56, 57) is increased, and thus the connection reliability is increased.

The present embodiment is only for illustrative purposes and does not limit the present invention at all. Therefore, various changes and modifications may be made for the present invention without deviating from the gist of the present invention. For example, the electronic component accommodated in the cavity 3 is not limited to MLCC, and any other type may be used as long as it is shaped like a flat plate. FIG. 10 illustrates the example in which the via holes (56, 57) are provided in both outer-layer wiring patterns (52, 53) so as to be connected to the MLCC 4. However, the present invention is not limited to such a structure, and only either the outer-layer wiring pattern 52 or the outer-layer wiring pattern 53 may be connected to the MLCC 4. Yet alternatively, only one outer-layer wiring pattern (52 or 53) may be formed.

Regarding the off-center arrangement of the electronic component (MLCC 4) in the cavity 3, it is off center in a direction (direction (A-A) in FIG. 1) that connects the electrode 41 and the electrode 42 in the present embodiment. However, that is not the only option, and the arrangement may be off center in a direction intersecting the direction (A-A). When inspecting whether the electronic component (MLCC 4) in a product inclines, it is sufficient to inspect whether the electronic component inclines in either the direction between the direction A-A in FIG. 1 or the direction intersecting the direction A-A.

The method for setting the electronic component (MLCC 4) to incline is not limited to the off-center arrangement in the cavity 3. Since an inclination may occur when the gravity center of the electronic component itself is shifted from the center of the wiring board, any other method that can cause a shifted gravity center may be employed. Alternatively, for the MLCC 4 described above, since an inclination occurs by providing a difference in the thickness of the electrodes (41, 42), such a method may also be employed.

When parts of an electronic component become more compact, the diameter of via holes to make electrical connections between conductive layers is also reduced. The diameter of via hole which conducts electricity between the electronic component and an upper conductive layer positioned above the electronic component is also reduced. When the contact area between the electronic component and the via hole is reduced, connection reliability is also lowered.

According to an embodiment of the present invention, a wiring board with a built-in electronic component exhibits improved connection reliability between the electronic component and a via hole, and according to another embodiment of the present invention is directed to a method of manufacturing the same.

According to one aspect of the present invention, a wiring board having a built-in electronic component includes: a core substrate having a cavity formed to penetrate through the core substrate in a thickness direction; an electronic component accommodated in the cavity and provided with conductive portions formed on an upper surface; filling resin to fill a space between a wall surface of the cavity and the electronic component; a first-surface-side resin insulation layer structured to cover first main surfaces of the core substrate and the electronic component; and a second-surface-side resin insulation layer structured to cover second main surfaces of the core substrate and the electronic component. In such a wiring board, the main surface of the electronic component inclines to the main surface of the core substrate, at least either the first-surface-side resin insulation layer or the second-surface-side insulation layer is provided with an upper-layer pattern and a via hole that connects the conductive portion of the electronic component to the upper-layer pattern, and the electronic component and the upper-layer pattern are not in contact with each other in a region where the via hole is not formed.

A wiring board with a built-in electronic component according to an embodiment of the present invention is manufactured by: positioning an electronic component in a cavity of a core substrate in which the cavity is formed to penetrate through the core substrate in a thickness direction; forming a first-surface-side resin insulation layer structured to cover a first main surface of the core substrate and a first main surface of the electronic component positioned inside the cavity; causing a portion of resin forming the first-surface-side resin insulation layer to flow into a gap between a wall surface of the cavity and the electronic component so that the gap is filled with the resin; forming a second-surface-side resin insulation layer that covers second main surfaces of the core substrate and the electronic component; filling the gap between the wall surface of the cavity and the electronic component with a portion of resin that forms the second-surface-side resin insulation layer in order to incline the electronic component with respect to the core substrate to the extent that any edge of the electronic component does not reach the first-surface-side resin insulation layer or the second-surface-side resin insulation layer; and forming an upper-layer pattern and a via hole that connects a conductive portion of the electronic component to the upper-layer pattern in either the first-surface-side resin insulation layer or the second-surface-side resin insulation layer.

In a wiring board with a built-in electronic component according to an embodiment of the present invention, the electronic component accommodated in the cavity is positioned with a posture inclined to the core wiring board. The via hole is provided in a conductive portion of the electronic component that inclines, and thus conduction with an upper-layer pattern is obtained. Therefore, a contact area between the via hole and the conductive portion of the electronic component is increased in proportion to an inclination angle as compared with a case where there is no inclination. On the other hand, owing to the inclination, the electronic component is not in contact with the upper-layer pattern in positions other than the via hole. Accordingly, improved connection reliability between the electronic component and the via hole is achieved in a wiring board with a built-in electronic component while there is no concern of short-circuiting.

In a wiring board with a built-in electronic component according to an embodiment of the present invention, the electronic component and the cavity may have a rectangular shape when seen on a planar surface, and a value of a tangent of an inclination angle between the main surface of the electronic component and the main surface of the core substrate may be within a range of 0.005 to 0.02 when the electronic component inclines in a longitudinal direction, and a range of 0.01 to 0.04 when the electronic component inclines in a transverse direction. If the inclination angle is too small, the effect of the inclination is not sufficient. On the other hand, if the inclination angle is too large, there is a concern that the electronic component will come into direct contact with the upper-layer pattern in positions other than the via hole. When the shape of the electronic component on a planar surface is a square, any direction may be set as a longitudinal direction.

In a wiring board with a built-in electronic component according to an embodiment of the present invention, a portion of the filling resin near the first-surface-side resin insulation layer may be contiguous from the first-surface-side resin insulation layer. A portion of the resin that forms the first-surface-side resin insulation layer is made to flow into a gap between a wall surface of the cavity and the electronic component during the manufacturing process. In this way, the above-described structure can be obtained by filling a space around the electronic component with the resin without increasing the number of processing steps.

In a wiring board with a built-in electronic component according to an embodiment of the present invention, for the distance between a wall surface of the cavity and one side of the electronic component may be at least 20% greater than the distance between another wall surface of the cavity and the opposite side of the electronic component. In this way, by positioning the electronic component in a distinctively off-centered manner with respect to the wall surfaces of the cavity, a difference in pressing back the resin from the second-surface-side resin insulation layer surely occurs between the one side and the opposite side of the electronic component during formation of the second-surface-side resin insulation layer. This causes the electronic component to rotate and to be inclined. For this reason, in a method of manufacturing the wiring board with a built-in electronic component according to an embodiment of the present invention, after the electronic component is positioned in the cavity, the distance between the wall surface of the cavity and the electronic component may be made different on one side of the electronic component and on the opposite of the electronic component before the electronic component is adjusted to be inclined with respect to the core substrate.

In a wiring board with a built-in electronic component according to an embodiment of the present invention, the first-surface-side resin insulation layer and the second-surface-side resin insulation layer may not contain a core member. This is because it is easy to form fine via holes in the first-surface-side resin insulation layer and the second-surface-side resin insulation layer.

In addition, in a wiring board with a built-in electronic component according to an embodiment of the present invention, the conductive portions of the electronic component may be arranged along opposite sides of the electronic component. Also, the measurement of the conductive portion in a direction that intersects the one side of the electronic component may be further greater than the larger one of the distance between the wall surface of the cavity and the one side and the distance between the wall surface of the cavity and the opposite side. With this structure, even though positioning accuracy of the electronic component in the cavity is not so high, the via hole for making electrical conduction between the conductive portion of the electronic component and the upper-layer pattern is not likely to deviate from a region in which the conductive portions are provided. Accordingly, a wiring board with a built-in electronic component according to an embodiment of the present invention achieves high reliability. In a wiring board with a built-in electronic component according to an embodiment of the present invention, an example of the electronic component may be a multilayer ceramic capacitor in which the conductive portions are formed to extend from a side surface to the main surface.

Obviously, numerous modifications and variations of the present invention are possible in light of the above teachings. It is therefore to be understood that within the scope of the appended claims, the invention may be practiced otherwise than as specifically described herein.

What is claimed is:

1. A wiring board with a built-in electronic component, comprising:
a core substrate having a cavity portion penetrating through the core substrate;
an electronic component accommodated in the cavity portion of the core substrate and comprising a body portion and a plurality of conductive portions formed on a surface of the body portion;
a filling resin filling a space formed in the cavity portion having the electronic component positioned in the cavity portion;
a first resin insulation layer formed on the core substrate such that the first resin insulation layer is covering the core substrate and the electronic component;
a second resin insulation layer formed on the core substrate on an opposite side with respect to the first resin insulation layer such that the second resin insulation layer is covering the core substrate and the electronic component;
a conductive pattern formed on the first resin insulation layer; and
a via hole conductor formed through the first resin insulation layer such that the via hole conductor is connecting one of the conductive portions of the electronic component and the conductive pattern formed on the first resin insulation layer,
wherein the electronic component is positioned in the cavity portion of the core substrate such that the electronic component is inclined with respect to surfaces of the core substrate and has a main surface forming an inclination angle with respect to a main surface of the core substrate.

2. The wiring board with a built-in electronic component according to claim 1, wherein the electronic component has a rectangular shape, the cavity portion of the core substrate has a rectangular shape, and the inclination angle between the main surface of the electronic component and the main surface of the core substrate has a tangent value which is within a range of 0.005 to 0.02, where the electronic component inclines in a longitudinal direction of the electronic component, and a range of 0.01 to 0.04, where the electronic components inclines in a transverse direction of the electronic component.

3. The wiring board with a built-in electronic component according to claim 1, wherein the electronic component has a rectangular shape, the cavity portion of the core substrate has a rectangular shape, and the inclination angle between the main surface of the electronic component and the main surface of the core substrate has a tangent value which is within a range of 0.005 to 0.02, where the electronic component inclines in a longitudinal direction of the electronic component.

4. The wiring board with a built-in electronic component according to claim 1, wherein the electronic component has a rectangular shape, the cavity portion of the core substrate has a rectangular shape, and the inclination angle between the main surface of the electronic component and the main surface of the core substrate has a tangent value which is within a range of 0.01 to 0.04, where the electronic components inclines in a transverse direction of the electronic component.

5. The wiring board with a built-in electronic component according to claim 1, wherein the filling resin includes a portion of a resin material of the first resin insulation layer.

6. The wiring board with a built-in electronic component according to claim 1, wherein the electronic component is positioned in the cavity portion of the core substrate such that a distance between one wall surface forming the cavity portion and one side of the electronic component is 20% greater than a distance between an opposite wall surface forming the cavity portion and an opposite side of the electronic component.

7. The wiring board with a built-in electronic component according to claim 1, wherein the first resin insulation layer comprises a resin material and does not contain a core member, and the second resin insulation layer comprises a resin material and does not contain a core member.

8. The wiring board with a built-in electronic component according to claim 1, wherein the conductive portions of the electronic component are formed along opposing sides of the electronic component, respectively, such that each of the conductive portions has a size in a direction intersecting the sides of the electronic component which is greater than a greater distance between a wall forming the cavity portion and one of the sides of the electronic component.

9. The wiring board with a built-in electronic component according to claim 1, wherein the electronic component is a multi-layer ceramic capacitor, and the conductive portions are formed on a dielectric body portion of the multi-layer ceramic capacitor such that the conductive portions are extending from one surface of the dielectric body portion to an opposite surface through side surfaces of the dielectric body portion, respectively.

10. The wiring board with a built-in electronic component according to claim 1, further comprising a second via hole conductor formed through the first resin insulation layer, wherein the via hole conductor and the second via hole conductor are connecting the conductive portions of the electronic component and the conductive pattern formed on the first resin insulation layer, respectively.

11. A method of manufacturing a wiring board with a built-in electronic component, comprising:
preparing a core substrate having a cavity portion penetrating through the core substrate;
positioning an electronic component in the cavity portion of the core substrate;
forming a first resin insulation layer on the core substrate such that the first resin insulation layer covers the core substrate and the electronic component positioned inside the cavity portion of the core substrate;
making a portion of a resin material forming the first resin insulation layer to flow into a gap formed between a wall forming the cavity portion and the electronic component such that the portion of the resin material fills the gap between the wall forming the cavity portion and the electronic component;
forming a second resin insulation layer on the core substrate on an opposite side with respect to the first resin insulation layer such that the second insulation layer covers the core substrate and the electronic component positioned inside the cavity portion of the core substrate;
making a portion of a resin material forming the second resin insulation layer to flow into the gap between the wall forming the cavity portion and the electronic component such that the electronic component is inclined with respect to surfaces of the core substrate and has a main surface forming an inclination angle with respect to a main surface of the core substrate;
forming a conductive pattern on one of the first resin insulation layer and the second resin insulation layer; and
forming a via hole conductor through the one of the first resin insulation layer and the second resin insulation layer such that the via hole conductor connects one of conductive portions of the electronic component and the conductive pattern formed on the one of the first resin insulation layer and the second resin insulation layer.

12. The method of manufacturing a wiring board with a built-in electronic component according to claim 11, further comprising determining a difference between a distance between one wall forming the cavity portion and one side of the electronic component and a distance between an opposite wall forming the cavity portion and an opposite side of the electronic component prior to inclining the electronic component positioned inside the cavity portion with respect to the surfaces of the core substrate.

13. The method of manufacturing a wiring board with a built-in electronic component according to claim 11, wherein the electronic component has a rectangular shape, the cavity portion of the core substrate has a rectangular shape, and the portion of the resin material forming the second resin insulation layer is made to flow into the gap such that the inclination angle between the main surface of the electronic component and the main surface of the core substrate has a tangent value which is within a range of 0.005 to 0.02, where the electronic component inclines in a longitudinal direction of the electronic component, and a range of 0.01 to 0.04, where the electronic components inclines in a transverse direction of the electronic component.

14. The method of manufacturing a wiring board with a built-in electronic component according to claim 11, wherein the electronic component has a rectangular shape, the cavity portion of the core substrate has a rectangular shape, and the portion of the resin material forming the second resin insulation layer is made to flow into the gap such that the inclination angle between the main surface of the electronic component and the main surface of the core substrate has a tangent value which is within a range of 0.005 to 0.02, where the electronic component inclines in a longitudinal direction of the electronic component.

15. The method of manufacturing a wiring board with a built-in electronic component according to claim 11, wherein the electronic component has a rectangular shape, the cavity portion of the core substrate has a rectangular shape, and the portion of the resin material forming the second resin insulation layer is made to flow into the gap such that the inclination angle between the main surface of the electronic component and the main surface of the core substrate has a tangent value which is within a range of 0.01 to 0.04, where the electronic components inclines in a transverse direction of the electronic component.

16. The method of manufacturing a wiring board with a built-in electronic component according to claim 11, wherein the electronic component is positioned in the cavity portion of the core substrate such that a distance between one wall surface forming the cavity portion and one side of the electronic component is 20% greater than a distance between an opposite wall surface forming the cavity portion and an opposite side of the electronic component.

17. The method of manufacturing a wiring board with a built-in electronic component according to claim 11, wherein the first resin insulation layer comprises a resin material and does not contain a core member, and the second resin insulation layer comprises a resin material and does not contain a core member.

18. The method of manufacturing a wiring board with a built-in electronic component according to claim 11, wherein the conductive portions of the electronic component are formed along opposing sides of the electronic component, respectively, and the portion of the resin material forming the second resin insulation layer is made to flow into the gap such that each of the conductive portions has a size in a direction intersecting the sides of the electronic component which is greater than a greater distance between a wall forming the cavity portion and one of the sides of the electronic component.

19. The method of manufacturing a wiring board with a built-in electronic component according to claim 11, wherein the electronic component is a multi-layer ceramic capacitor, and the conductive portions are formed on a dielectric body portion of the multi-layer ceramic capacitor such that the conductive portions are extending from one surface of the dielectric body portion to an opposite surface through side surfaces of the dielectric body portion, respectively.

20. The method of manufacturing a wiring board with a built-in electronic component according to claim 11, further comprising forming a second via hole conductor through the one of the first resin insulation layer and the second resin insulation layer, wherein the via hole conductor and the second via hole conductor connect the conductive portions of the electronic component and the conductive pattern formed on the one of the first resin insulation layer and the second resin insulation layer, respectively.
